(19) United States
(12) Patent Application Publication
(10) Pub. No.: US 2023/0408558 A1
(43) Pub. Date: Dec. 21, 2023

(54) MACHINE LEARNING FOR MEASUREMENT USING LINEAR RESPONSE EXTRACTED FROM WAVEFORM

(71) Applicant: Tektronix, Inc., Beaverton, OR (US)

(72) Inventors: Kan Tan, Portland, OR (US); John J. Pickerd, Hillsboro, OR (US)

(73) Assignee: Tektronix, Inc., Beaverton, OR (US)

(21) Appl. No.: 18/210,583

(22) Filed: Jun. 15, 2023

Related U.S. Application Data
(60) Provisional application No. 63/353,960, filed on Jun. 21, 2022.

(51) Int. Cl. G01R 19/25; G06N 3/0442; G06N 3/045; G06N 3/08

(52) U.S. Cl. CPC G01R 19/2506; G06N 3/0442; G06N 3/045; G06N 3/08

(57) ABSTRACT

A test and measurement instrument has one or more ports configured to receive a signal one or more devices under test (DUT), and one or more processors configured to execute code that causes the one or more processors to: acquire a waveform from the signal, derive a pattern waveform from the waveform, perform linear response extraction on the pattern waveform, present one or more data representations including a data representation of the extracted linear response to a machine learning system, and receive a prediction for a measurement from the machine learning system. A method of performing a measurement on a waveform includes acquiring the waveform at a test and measurement device, deriving a pattern waveform from the waveform, performing linear response extraction on the pattern waveform, presenting one or more data representations including a data representation of the extracted linear response to a machine learning system, and receiving a prediction of the measurement from the machine learning system.

### CROSS-REFERENCE TO RELATED APPLICATIONS

This disclosure claims benefit of U.S. Provisional Application No. 63/353,960, titled “EXTRACTED LINEAR FIT PULSE BASED MACHINE LEARNING FOR MEASUREMENT,” filed on Jun. 21, 2022, the disclosure of which is incorporated herein by reference in its entirety.

### TECHNICAL FIELD

This disclosure relates to test and measurement instruments and systems, and more particularly to a machine learning component of a test and measurement system.

### DESCRIPTION

Machine Learning (ML) techniques can significantly improve the speed of complex measurements. The measurement speed improvement translates to the improvement of production throughput. For the high-speed signal testing, the eye diagram of the signal has been used by machine learning to get measurement results. See, e.g., S. Varughese, A. Melgar, V. A. Thomas, P. Zivny, S. Hazzard and S. E. Ralph, “Accelerating Assessments of Optical Components Using Machine Learning: TDECQ as Demonstrated Example,” in Journal of Lightwave Technology, vol. 39, no. 1, pp. 64-72, 2021 (hereinafter “Varughese”). The full or partial pattern waveforms are also used for machine learning for measurement. See Varughese. The short pattern waveform database is introduced for machine learning too, as described in U.S. patent application Ser. No. 17/747,954, titled “SHORT PATTERN WAVEFORM DATABASE BASED MACHINE LEARNING FOR MEASUREMENT,” filed May 18, 2022 (hereinafter “the '954 application”), the contents of which are hereby incorporated by reference. This disclosure describes a new type of data that can be used for machine learning for measurement: an extracted linear fit pulse.

When the signal speed increases, the equalizers in transmitter and receiver are widely used to improve the system performance. For example, PCIE (Peripheral Component Interconnect Express) Gen6 receiver has a 16-tap DFE (Decision Feedback Equalizer) in addition to a CTLE (Continuous Time Linear Equalization) filter. When the receivers have equalizers, some of the measurements are performed on the equalized signals. For example, in PCIE Gen6, the eye height and eye width measurements are defined based on the eye diagram of the equalized waveform. In another example, IEEE 802.3 standards for 100G/400G specify the transmitter and dispersion eye closure (TDECQ) measurement as key pass/fail criteria for 26 GBaud and 53 GBaud PAM4 optical signaling. The TDECQ measurement involves a 5-tap FFE (Feed Forward Equalizer).

For complex and time-consuming measurements, machine learning techniques can provide significant improvement in the measurement speed. The information contained in the data used by machine learning affects the machine learning results. The '954 application describes the data containing short pattern waveforms for machine learning. The advantage is that the data has the time sequence information. However, the selected short patterns only appear in a portion of the whole data pattern.

### BRIEF DESCRIPTION OF THE DRAWINGS

FIG. 1 shows an example of a Pulse Amplitude Modulation-4 (PAM4) waveform.

FIG. 2 shows an example of an eye diagram obtained from a PAM4 waveform.

FIG. 3 shows an example of a linear fit pulse extracted from a PAM4 waveform.

FIG. 4 shows an example of a vertical histogram at the center of the eye diagram.

FIG. 5 shows histogram locations in an eye diagram.

FIG. 6 shows an embodiment of an image containing an extracted pulse and vertical histogram.

FIG. 7 shows embodiments of images containing an extracted linear fit pulse and vertical histogram from four waveforms.

FIG. 8 shows an embodiment of an extracted linear fit pulse based machine learning model.

FIG. 9 shows a graphical representation of a machine learning prediction versus label for a test set.

FIG. 10 shows an embodiment of a test and measurement instrument.

### DETAILED DESCRIPTION

Machine learning techniques can provide significant improvement in the measurement speed, as mentioned above. The U.S. patent application Ser. No. 17/747,954 application (the '954 application) describes data that contains short pattern waveforms for machine learning. The advantage is that the data has the time sequence information. However, the selected short patterns only appear in a portion of the whole data pattern. This can give rise to complications.

In certain conditions, obtaining sufficient appearances of the selected short patterns may involve a long waveform. The embodiments here use an extracted linear response approach. A linear-fit-pulse-based approach uses all the samples in the waveform, so it is more efficient to get the needed data for machine learning, since it is not constrained by the selection of the short patterns and the data pattern of the waveform.

For the measurements that require equalizers, to get more accurate results the input data to the neural network should contain time sequence information, since the equalizers operate on the time sequenced samples. The regular eye diagram data has lost the time sequence information between symbols. The full pattern waveform could have a large size, making it slow to train the neural network and hard to fit into the machine learning model. The short pattern waveform data set only uses a portion of the waveform, so it could be less efficient.

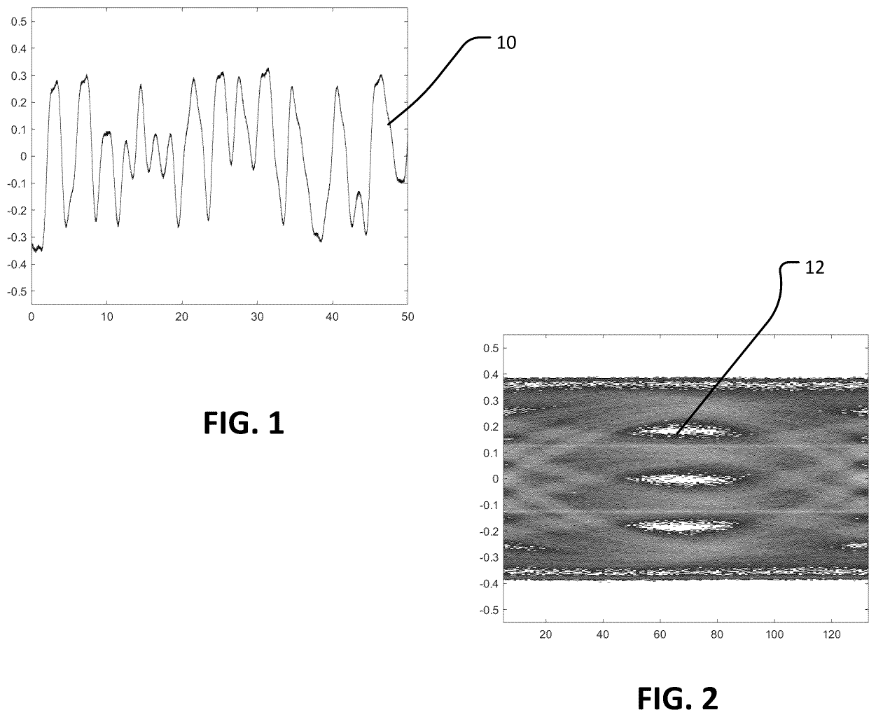

The discussion here may use the linear fit pulse as an example of the linear response extracted from the waveform. Other linear responses include impulse response and step response, among others. The linear fit pulse extraction technique has been used for measurements and equalizer adaptations. The linear fit pulse contains the time sequence information that is common for all data. The time sequence information reflects the inter-symbol-interference. The time sequence information can help determine equalization parameters such as FFE taps, DFE taps, and CTLE. FIG. 1 shows an example of a waveform 10, and FIG. 2 shows the eye diagram of the waveform with an eye center shown at 12.

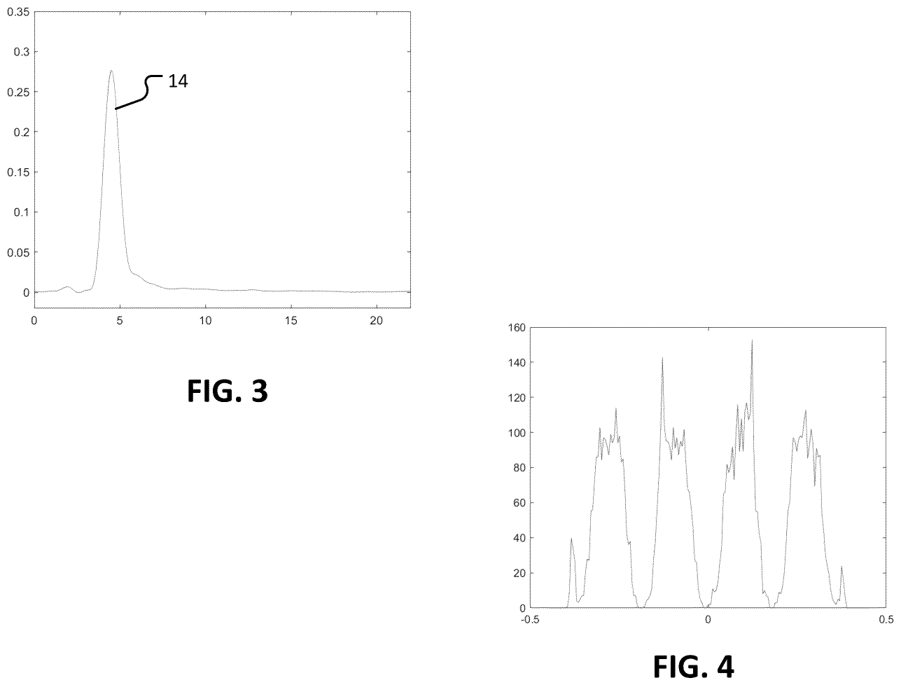

FIG. 3 shows the linear fit pulse 14 extracted from the whole waveform.

Depending on the measurement requirements, other data can also be used with the extracted linear response to be provided to the machine learning system. For example, a signal-to-noise ratio (SNR) measurement may use the vertical histogram at the eye center, as shown in FIG. 4. In FIGS. 1-3, the y-axis displays the amplitude of the waveform. In FIG. 4, the x-axis shows the amplitude with unit of Volts, the y-axis shows the number of hits. The three locations on the x-axis that show zero hits, i.e. at amplitudes of approximately −0.2 V, 0 V, and 0.2 V, correspond to locations of the three eye openings, e.g. eye opening 12, shown in the eye diagram of FIG. 2.

For different choices of machine learning methods, the extracted linear fit pulse and the vertical histogram can be arranged in the appropriate formats. For example, the linear response and the vertical histogram both comprise 1-Dimensional vectors that can be treated as a 1-D data set and fed into neural networks that handle 1-D data, for example, a recurrent neural network (RNN), the long short-term memory (LSTM), and the 1-D convolutional neural network (CNN). The data set can also be organized as tabular data.

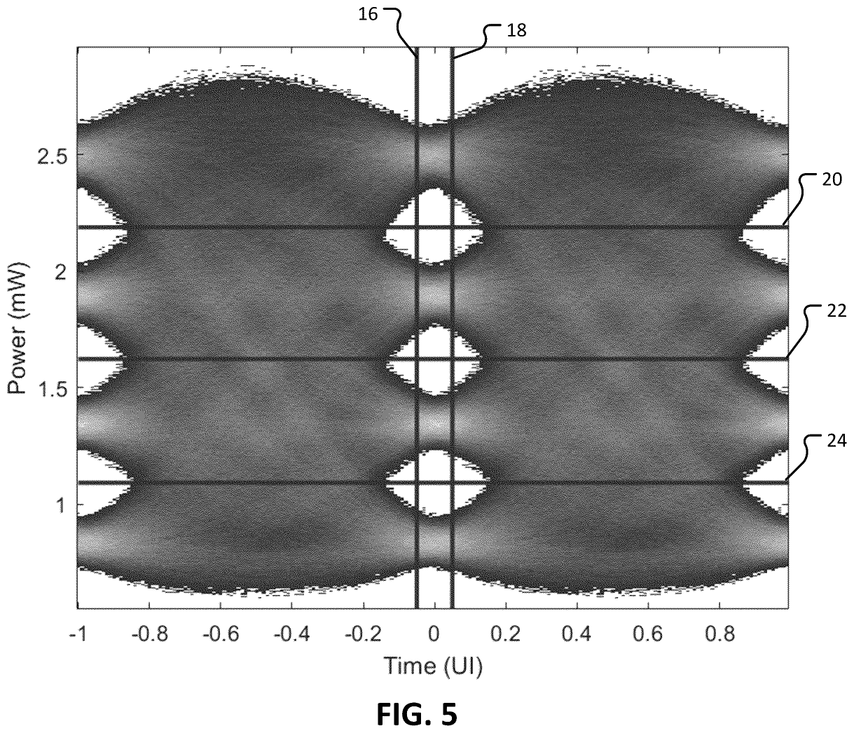

FIG. 5 shows locations of possible vertical histograms at 16 and 18 on either side of the eye center, and possible horizontal histograms at 20, 22, and 24, each on an eye center.

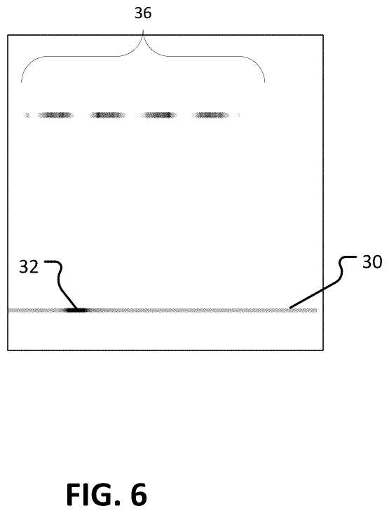

Another embodiment places the data into a 2-D image and uses the 2-D CNN models. A residual neural network (ResNet) is another 2-D neural network that could be used. FIG. 6 shows the extracted linear fit pulse extracted from the waveform, as shown in FIG. 3, as a data representation to be provided to the machine learning system. The grey line 30 at the bottom represents the extracted linear fit pulse where the darker color, such as in region 32, means a higher amplitude in the linear fit pulse. The grey line 36 on the top represents the vertical histogram shown in FIG. 4, and the darker color that appears in bars represents more hits, or occurrences. The darkness of the pixels represents the amplitude of the extracted pulses, and the number of occurrences, hits, on the histogram. To contrast with the '954 short pattern waveform application, the 2-D image has limited space, so the short patterns were used to fit. The embodiments here can use each of the 224 lines in a 224×224 2-D image to represent amplitude by the darkness of the pixels. This allows the image to accommodate long pulse responses, and/or multiple histograms taken from either vertical or horizontal slices at multiple different locations of an eye diagram.

The test and measurement instrument, such as an oscilloscope or other instrument that can acquire and process waveform data, may present these data representations to the machine learning system. The machine learning system may reside on the test and measurement instrument or may reside in a separate computing device that connects with the instrument. The embodiments may take the form of code executed by one or more processors, and the processors may reside on one device or multiple devices.

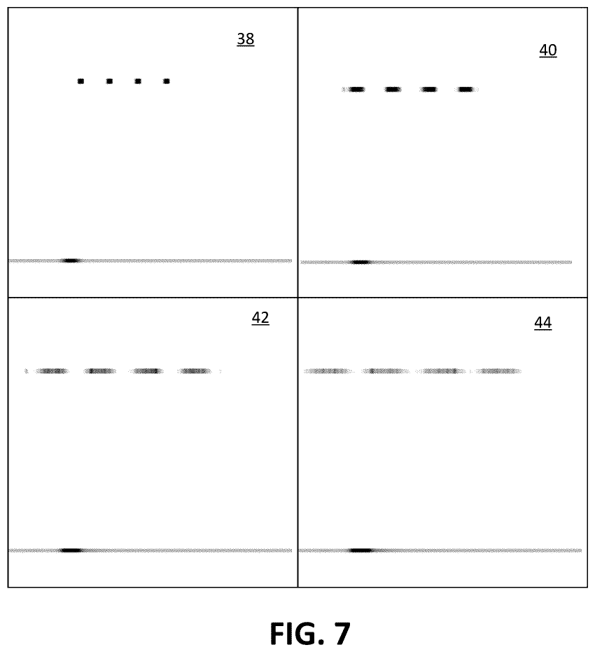

Training the CNN requires a large training data set. In one embodiment, a simulation generates the data set. The images shown in FIG. 7 represent four different signals with different linear fit pulses and different vertical histograms as data representations 38, 40, 42, and 44.

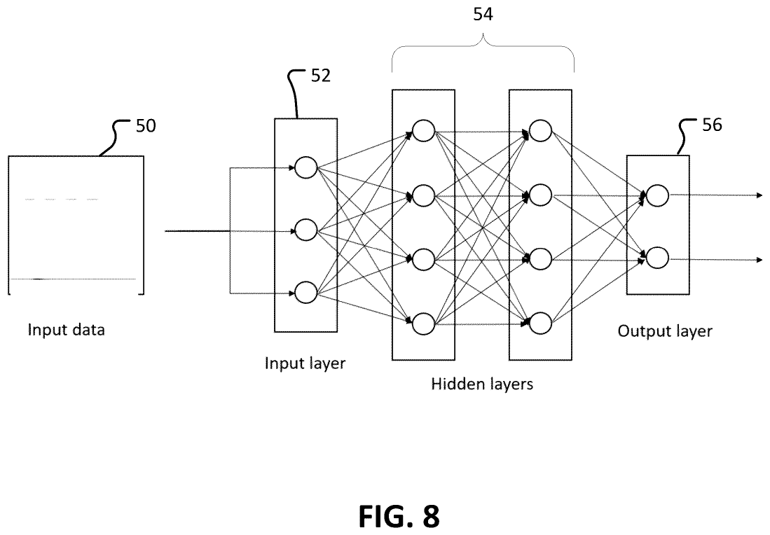

FIG. 8 shows one embodiment of a machine learning system that uses representations of the extracted linear fit pulse and vertical histogram as input data 50, and the CNN model having an input layer 52. CNN could have multiple hidden layers 54, and an output layer 56. Many existing deep learning CNN models can provide measurements, assistance with transmitting tuning, and adaptation of equalizers. The neural network could have various structures. When a pre-trained deep learning network model is used, the transfer learning could be performed. In one embodiment, only the last fully connected layer may be trained with the data set having the linear fit pulse. The one or more processors, in this embodiment, normalize the data set fed into the neural network. The results are then de-normalized. For example, the label values are normalized for neural network training. After the neural network training is complete, and the trained network performs the prediction, the prediction result is de-normalized which is the inverse map of normalization.

The data set may comprise the data representations above and known measurement values associated with the data representation, to train the machine learning system to learn to associate a particular data representation with a measurement value. This allows the machine learning system to provide measurement values to electronic devices much more quickly than performing the actual measurements.

One embodiment of using extracted linear responses from waveforms to make measurements related to the device generating the waveform involves several steps. Acquire the waveform on a test and measurement instrument such as a real-time or equivalent-time oscilloscopes. The instrument then performs software or hardware clock recovery to determine the pattern waveform.

The instrument then performs linear response extractions, such as linear fit pulse extraction, through the fitting algorithms described in “IEEE 802.3ba 40 Gb/s and 100 Gb/s Ethernet Standard,” http://www.ieee802.org/3/2010, the contents of which are hereby incorporated by reference into this disclosure. To improve the speed, the fitting algorithms can be applied to a portion of the waveform, for example, on a portion that covers about 10,000 symbols. Since the fitting algorithms use every symbol, using 10,000 symbols provides sufficient data to get the accurate linear fit pulse, or other linear response. Also, the average over multiple repeats of the pattern waveform can help to reduce the noise and get the more precise linear response.

While the trained machine learning system may operate just on the extracted linear response, one could provide more data representations for each waveform. These include other data types that provide related information for the measurement. For example, the vertical histogram at the center of the UI is selected for SNR measurement. Two vertical histograms around the center of the UI are selected for TDECQ measurement. For jitter measurement, the horizontal histogram at the edge crossing level(s) is selected. Multiple vertical histograms, multiple horizontal histograms, and combinations of vertical histograms and horizontal histograms can also be used.

The process then chooses the data representations that fit the neural network for machine learning. For example, the extracted linear fit pulse and the vertical histogram are represented in the 2-D image shown in FIG. 6. The extracted linear fit pulse and 1-D histogram can also be represented in 1-D data set. A user interface of the test and measurement instrument may allow the user to select the data representations. Besides the linear fit pulse response, other linear responses such as impulse response, step response can also be used. The linear fit pulse data set can be combined with selected short pattern waveforms data set for machine learning.

The above discussion focuses on using a trained machine learning system. A part of the process may involve training the machine learning system as discussed above. In one embodiment, a simulation may be run to gather waveforms and their associated measurements to provide the training data set.

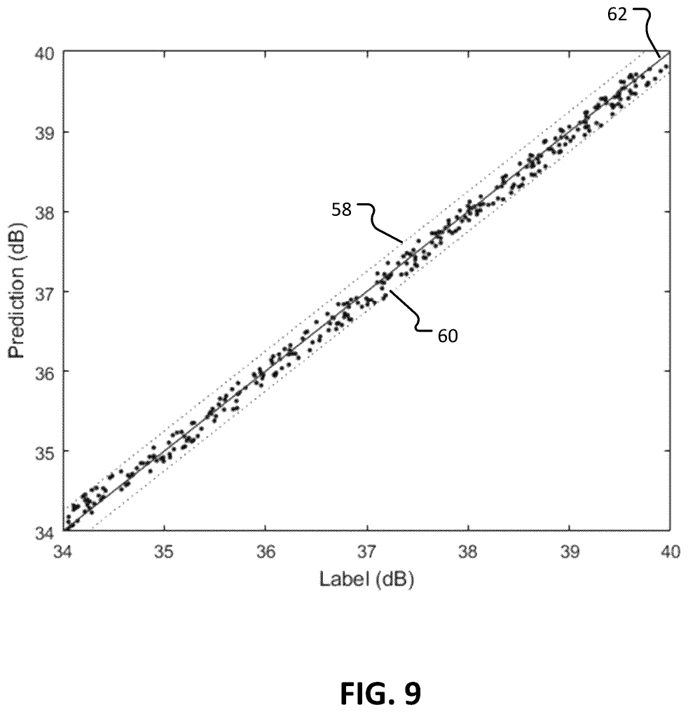

In an example, according to an embodiment of the disclosure, a CNN model is trained to perform the SNR measurement. The data is generated from simulation. The transfer learning is performed based on a pre-trained Resnet34. The problem is set up as a regression problem. The Pytorch and FastAI packages are used to train the model and test. The test result is shown in FIG. 9, all predictions are within +/−0.25 dB range from the target results, the labels. The RMSE on the test set is 0.108 dB. With the target result range from 34 dB to 40 dB, the RMSE relative to the range is about 0.108/6=1.8%. The solid line 62 represents a perfect prediction and the dashed lines 58 and 60 represent the ±0.25 dB boundary.

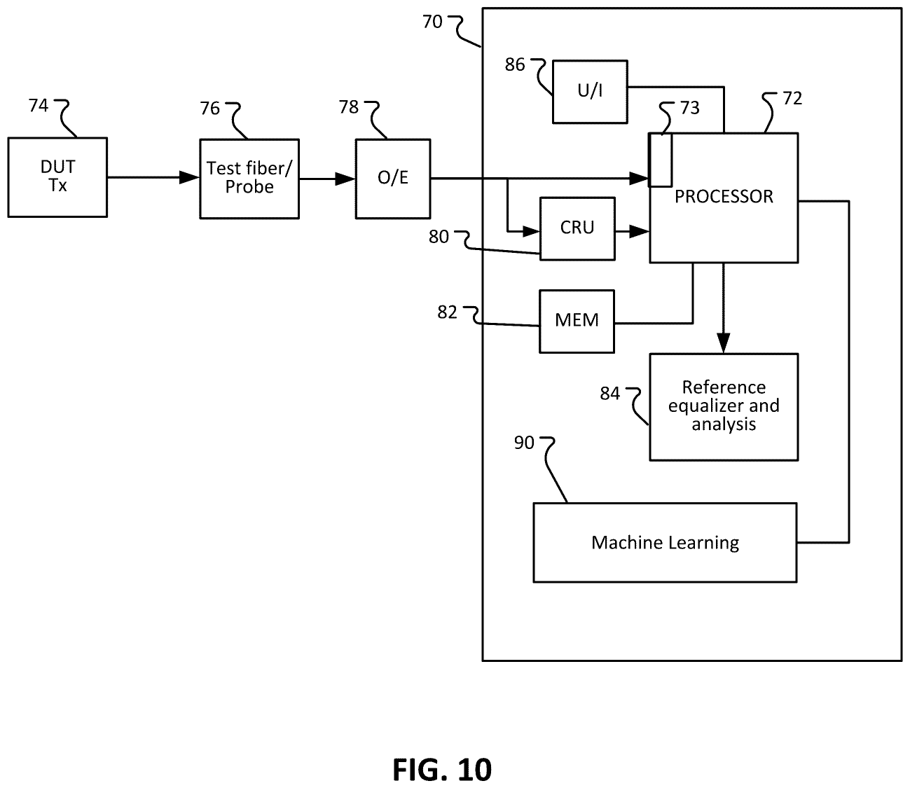

The machine learning system may take the form of programmed models operating on one or more processors. As mentioned above, the embodiments may involve one or more processors executing code that causes the processors to perform the various tasks. FIG. 10 shows an embodiment of a testing setup in the instance of an optical transmitter 74 as a DUT. The testing setup includes a test and measurement system that may include a test and measurement instrument such as an oscilloscope 70. The test and measurement instrument 70 receives a signal from the DUT 74 through an instrument probe 76. In the case of an optical transmitter, the probe will typically comprise a test fiber coupled to an optical to electrical converter 78 that provides a signal to the test and measurement instrument through one or more ports 73. Two ports may be used for differential signaling, while one port is used for single channel signaling. The signals are sampled and digitized by the instrument to become waveforms. A clock recovery unit (CRU) 80 may recover the clock signal from the data signal if the test and measurement instrument 70 comprises a sampling oscilloscope for example. A software clock recovery can be used on a real-time oscilloscope.

The test and measurement instrument has one or more processors represented by processor 72, a memory 82 and a user interface 86. The memory may store executable instructions in the form of code that, when executed by the processor, causes the processor to perform tasks. User interface 86 of the test and measurement instrument allows a user to interact with the instrument 70, such as to input settings, configure tests, etc. The test and measurement instrument may also include a reference equalizer and analysis module 84.

The embodiments here employ machine learning in the form of a machine learning network 90, such a deep learning network. The machine learning network may include a processor that has been programmed with the machine learning network as either part of the test and measurement instrument, or to which the test and measurement instrument has access. As test equipment capabilities and processors evolve, the one or more processors such as 72 may include both.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc., that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

The previously described versions of the disclosed subject matter have many advantages that were either described or would be apparent to a person of ordinary skill. Even so, these advantages or features are not required in all versions of the disclosed apparatus, systems, or methods.

### EXAMPLES

Illustrative examples of the disclosed technologies are provided below. An embodiment of the technologies may include one or more, and any combination of, the examples described below.

Example 1 is a test and measurement instrument, comprising: one or more ports configured to receive a signal from one or more devices under test (DUT); and one or more processors configured to execute code that causes the one or more processors to: acquire a waveform from the signal; derive a pattern waveform from the waveform; perform linear response extraction on the pattern waveform; present one or more data representations including a data representation of the extracted linear response to a machine learning system; and receive a prediction for a measurement from the machine learning system.

Example 2 is the test and measurement instrument of Example 1, wherein the machine learning system employs a neural network that handles one-dimensional data and the code that causes the one or more processors to present the one or more data representations comprises code that causes the one or more processors to present a one-dimensional data set comprising a vertical histogram at an eye center of an eye diagram representation of the waveform.

Example 3 is the test and measurement instrument of either of Examples 1 or 2, wherein the machine learning system employs one or more of a recurrent neural network, a long short-term memory neural network, and a one-dimensional convolutional neural network.

Example 4 is the test and measurement instrument of any of Examples 1 through 3, wherein the machine learning system employs a neural network that handles two-dimensional data and the code that causes the one or more processors to present the one or more data representations comprises code that causes the one or more processors to present a two-dimensional data set comprising the extracted linear response and at least one histogram.

Example 5 is the test and measurement instrument of any of Examples 1 through 4, wherein the two-dimensional data includes pixels having a darkness that corresponds to one of an amplitude of the extracted linear response and a number of hits in a histogram.

Example 6 is the test and measurement instrument of any of Examples 1 through 5, wherein the machine learning system employs one or more of a two-dimensional convolutional neural network, and a residual neural network.

Example 7 is the test and measurement instrument of any of Examples 1 through 6, wherein the code that causes the one or more processors to present the one or more data representations to the machine learning system causes the one or more processors to normalize the one or more data representations prior to presenting the one or more data representations to the machine learning system, and to de-normalize the prediction of the measurement received from the machine learning system.

Example 8 is the test and measurement instrument of any of Examples 1 through 7, wherein the one or more processors are further configured to execute code that causes the one or more processors to train the machine learning system for a selected measurement.

Example 9 is the test and measurement instrument of Example 8, wherein the code that causes the one or more processors to train the machine learning system comprises code that causes the one or more processors to provide simulated training data of the data representations from simulated waveforms and a resulting measurement value for the selected measurement to the machine learning system.

Example 10 is a method of performing a measurement on a waveform, comprising: acquiring the waveform at a test and measurement device; deriving a pattern waveform from the waveform; performing linear response extraction on the pattern waveform; and presenting one or more data representations including a data representation of the extracted linear response to a machine learning system; and receiving a prediction of the measurement from the machine learning system.

Example 11 is the method of Example 10, wherein performing linear response extraction comprises performing extraction of one of a linear fit pulse, impulse response, and step response.

Example 12 is the method of either of Examples 10 or 11, wherein the one or more data representations comprise one or more of a vertical histogram at the center of a unit interval of an eye diagram representation of the waveform, two vertical histograms around a center of the unit interval, and a horizontal histogram at an edge of crossing levels of the eye diagram.

Example 13 is the method of any of Examples 10 through 12, wherein the one or more data representations includes pixels having a darkness that corresponds to one of an amplitude of the extracted linear response and a number of hits in a histogram.

Example 14 is the method of Examples 10 through 13, wherein presenting the one or more data representations comprises presenting a one-dimensional data set comprised of a vertical histogram at an eye center of an eye diagram representation of the waveform.

Example 15 is the method of Examples 10 through 14, wherein presenting the one or more data representations comprises presenting a two-dimensional image, and wherein the two-dimensional image comprises the extracted linear response and at least one histogram.

Example 16 is the method of Example 15, wherein the at least one histogram comprises at least one selected from a vertical histogram at an eye center of an eye diagram representation of the waveform, a pair of two histograms around a center of a unit interval of the eye diagram, and a horizontal histogram at edge crossing levels of the eye diagram.

Example 17 is the method of Examples 10 through 16, further comprising normalizing the one or more data representations prior to presenting the one or more data representations to the machine learning system, and de-normalizing the measurement after receiving the prediction of the measurement from the machine learning system.

Example 18 is the method of Examples 10 through 16, further comprising training the machine learning system for a selected measurement.

Example 19 is the method of Example 18, further comprising using simulated training data of the one or more data representations from simulated waveforms and a resulting measurement value for the selected measurement.

Example 20 is the method of Examples 10 through 19, wherein the measurement comprises one of signal-to-noise ratio, transmitter dispersion eye closure quaternary (TDECQ), and jitter.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
one or more ports configured to receive a signal from one or more devices under test (DUT); and
one or more processors configured to execute code that causes the one or more processors to:
acquire a waveform from the signal;
derive a pattern waveform from the waveform;
perform linear response extraction on the pattern waveform;
present one or more data representations including a data representation of the extracted linear response to a machine learning system; and
receive a prediction for a measurement from the machine learning system.

2. The test and measurement instrument as claimed in claim 1, wherein the machine learning system employs a neural network that handles one-dimensional data and the code that causes the one or more processors to present the one or more data representations comprises code that causes the one or more processors to present a one-dimensional data set comprising a vertical histogram at an eye center of an eye diagram representation of the waveform.

3. The test and measurement instrument as claimed in claim 1, wherein the machine learning system employs one or more of a recurrent neural network, a long short-term memory neural network, and a one-dimensional convolutional neural network.

4. The test and measurement instrument as claimed in claim 1, wherein the machine learning system employs a neural network that handles two-dimensional data and the code that causes the one or more processors to present the one or more data representations comprises code that causes the one or more processors to present a two-dimensional data set comprising the extracted linear response and at least one histogram.

5. The test and measurement instrument as claimed in claim 4, wherein the two-dimensional data includes pixels having a darkness that corresponds to one of an amplitude of the extracted linear response and a number of hits in a histogram.

6. The test and measurement instrument as claimed in claim 1, wherein the machine learning system employs one or more of a two-dimensional convolutional neural network, and a residual neural network.

7. The test and measurement instrument as claimed in claim 1, wherein the code that causes the one or more processors to present the one or more data representations to the machine learning system causes the one or more processors to normalize the one or more data representations prior to presenting the one or more data representations to the machine learning system, and to de-normalize the prediction of the measurement received from the machine learning system.

8. The test and measurement instrument as claimed in claim 1, wherein the one or more processors are further configured to execute code that causes the one or more processors to train the machine learning system for a selected measurement.

9. The test and measurement instrument as claimed in claim 8, wherein the code that causes the one or more processors to train the machine learning system comprises code that causes the one or more processors to provide simulated training data of the data representations from simulated waveforms and a resulting measurement value for the selected measurement to the machine learning system.

10. A method of performing a measurement on a waveform, comprising:
acquiring the waveform at a test and measurement device;
deriving a pattern waveform from the waveform;
performing linear response extraction on the pattern waveform;
presenting one or more data representations including a data representation of the extracted linear response to a machine learning system; and
receiving a prediction of the measurement from the machine learning system.

11. The method as claimed in claim 10, wherein performing linear response extraction comprises performing extraction of one of a linear fit pulse, impulse response, and step response.

12. The method as claimed in claim 10, wherein the one or more data representations comprise one or more of a vertical histogram at the center of a unit interval of an eye diagram representation of the waveform, two vertical histograms around a center of the unit interval, and a horizontal histogram at an edge of crossing levels of the eye diagram.

13. The method as claimed in claim 10, wherein the one or more data representations includes pixels having a darkness that corresponds to one of an amplitude of the extracted linear response and a number of hits in a histogram.

14. The method as claimed in claim 10, wherein presenting the one or more data representations comprises presenting a one-dimensional data set comprising a vertical histogram at an eye center of an eye diagram representation of the waveform.

15. The method as claimed in claim 10, wherein presenting the one or more data representations comprises presenting a two-dimensional image, and wherein the two-dimensional image comprises the extracted linear response and at least one histogram.

16. The method as claimed in claim 15, wherein the at least one histogram comprises at least one selected from a vertical histogram at an eye center of an eye diagram representation of the waveform, a pair of two histograms around a center of a unit interval of the eye diagram, and a horizontal histogram at edge crossing levels of the eye diagram.

17. The method as claimed in claim 10, further comprising normalizing the one or more data representations prior to presenting the one or more data representations to the machine learning system, and de-normalizing the measurement after receiving the prediction of the measurement from the machine learning system.

18. The method as claimed in claim 10, further comprising training the machine learning system for a selected measurement.

19. The method as claimed in claim 18, further comprising using simulated training data of the one or more data representations from simulated waveforms and a resulting measurement value for the selected measurement.

20. The method as claimed in claim 10, wherein the measurement comprises one of signal-to-noise ratio, transmitter dispersion eye closure quaternary (TDECQ), and jitter.
